(19) United States
(12) Patent Application Publication
(10) Pub. No.: US 2025/0143044 A1
(43) Pub. Date: May 1, 2025

(54) MULTI-CHANNEL LIGHT EMITTING DIODE PACKAGE STRUCTURE

(71) Applicant: LITE-ON TECHNOLOGY CORPORATION, TAIPEI CITY (TW)

(72) Inventors: ERH-CHAN HSU, Tainan City (TW); HOU-TE LEE, KAOHSIUNG CITY (TW); HAN-YIN YU, TAIPEI CITY (TW)

(21) Appl. No.: 18/925,035

(22) Filed: Oct. 24, 2024

Related U.S. Application Data
(60) Provisional application No. 63/545,969, filed on Oct. 27, 2023.

(30) Foreign Application Priority Data
Aug. 23, 2024 (CN) 202422050388.8

(51) Int. Cl. H01L 33/62; H01L 25/16; H01L 33/50; H01L 33/60

(52) U.S. Cl. CPC H10H 20/857; H01L 25/167; H10H 20/8514; H10H 20/856

(57) ABSTRACT

A multi-channel light emitting diode package structure includes a supporting unit, a driver chip, at least one upper light emitting chip, and a lower light emitting chip. The supporting unit has a top supporting surface, and includes a first accommodating portion and a second accommodating portion recessed from the top supporting surface. The driver chip is disposed in the first accommodating portion, and a top surface of the driver chip is lower than the top supporting surface of the supporting unit. At least one upper lighting chip is disposed on the top supporting surface of the supporting unit. A lower lighting chip is disposed in the second accommodating portion. A top surface of the lower lighting chip is lower than the top supporting surface of the supporting unit. The second accommodating portion is filled with phosphor materials and the phosphor materials completely cover the lower lighting chip.

### CROSS-REFERENCE TO RELATED PATENT APPLICATION

This application claims the benefit of priority to the U.S. Provisional Patent Application Ser. No. 63/545,969, filed on Oct. 27, 2023, and China Patent Application No. 202422050388.8, filed on Aug. 23, 2024, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a multi-channel light emitting diode (LED) package structure, and more particularly to an LED package structure having a plurality of light emitting diode (LED) chips, and a driver chip (integrated circuit), wherein the driver chip can be used to adjust the lighting status of the LED chips.

### BACKGROUND OF THE DISCLOSURE

Large LCD displays, such as an automotive electronic information system, require a dimmable backlight light-emitting diode (LED) light sources, or multi-channel LED devices. A multi-channel LED device usually includes a substrate, white or amber LEDs, LEDs of other colors, and an LED driver chip.

In the currently available multi-channel light-emitting diode devices, the arrangement of white or amber LEDs, LEDs of other colors, and driver chips causes the problem of light being blocked. In one arrangement, white or amber LEDs, LEDs of other colors, and driver chips are all placed on the top surface of the substrate. The disadvantage is that the driver chip blocks a side light of the LEDs of other colors, so that the intensity and viewing angle of the light are limited. In addition, blue light may illuminate the phosphors on a periphery of white or amber LEDs, causing a unexpected mixed light. In another arrangement, a blocking wall is used to separate white or amber LEDs from LEDs of other colors. This method will also limit the intensity and viewing angle of the light.

Therefore, how to improve the structure design to improve the lighting effect of the multi-channel LED package structure to overcome the above defects has become one of the issues that need to be solved in this technology field.

### SUMMARY OF THE DISCLOSURE

In response to the above-referenced technical inadequacies, the present disclosure provides a multi-channel LED package structure that can increase light intensity and viewing angles, so as to improve the lighting effect. In order to solve the above-mentioned problems, one of the technical aspects adopted by the present disclosure is to provide a multi-channel LED package structure, which includes a supporting unit, a driver chip, at least one upper light emitting chip, and a lower light emitting chip. The supporting unit has a top supporting surface. The supporting unit including a first accommodating portion and a second accommodating portion that both are concaved from the top supporting surface. The driver chip is disposed in the first accommodating portion, and a top surface of the driver chip is lower than a top surface of the supporting unit. The at least one upper light emitting chip is disposed on the top supporting surface of the supporting unit. The lower light emitting chip is disposed in the second accommodating portion. The lower light emitting chip has a top surface lower than the top supporting surface of the supporting unit. The second accommodating portion is filled with phosphor materials, and the phosphor materials completely cover the lower light emitting chip.

Therefore, in the multi-channel LED package structure provided by the present disclosure, by virtue of concavely forming a first accommodating portion and a second accommodating portion on the supporting unit, disposing the driver chip in the first accommodating portion, disposing the at least one upper light emitting chip on the top supporting surface of the supporting unit, and disposing the lower light emitting chip in the second accommodating portion, so that the light from the at least one upper light emitting chip and the lower light emitting chip are not obstructed, to increase the light intensity and the viewing angle. Therefore, the lighting effect of the multi-channel light emitting diode package structure is enhanced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a cross-sectional view of a multi-channel LED package structure according to the present disclosure;

FIG. 2 is an enlarged view of a part II of FIG. 1;

FIG. 3 is an enlarged view of a part III of FIG. 2;

FIG. 4 is an enlarged view of a part IV of FIG. 1;

FIG. 5 is a top view of the multi-channel LED package structure having an upper lighting chip according to the present disclosure;

FIG. 6 is a top view of the multi-channel LED package structure having three upper lighting chips according to the present disclosure; and

FIG. 7 is a side view of the multi-channel LED package structure having three upper lighting chips according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present disclosure, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

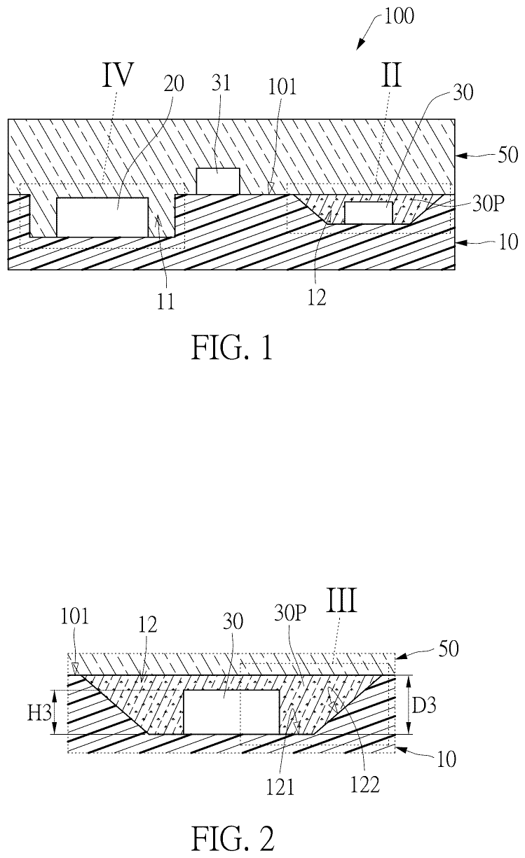

Referring to FIG. 1, an embodiment of the present disclosure provide a multi-channel light emitting diode (LED) package structure 100, hereinafter or referred to the LED package structure 100. The LED package structure 100 includes a supporting unit 10, a driver chip 20, at least one upper lighting chip 31, and a lower lighting chip 30. The supporting unit 10 is defined with a top supporting surface 101. The supporting unit 10 further includes a first accommodating portion 11 and a second accommodating portion 12 that are recessed by the top supporting surface 101.

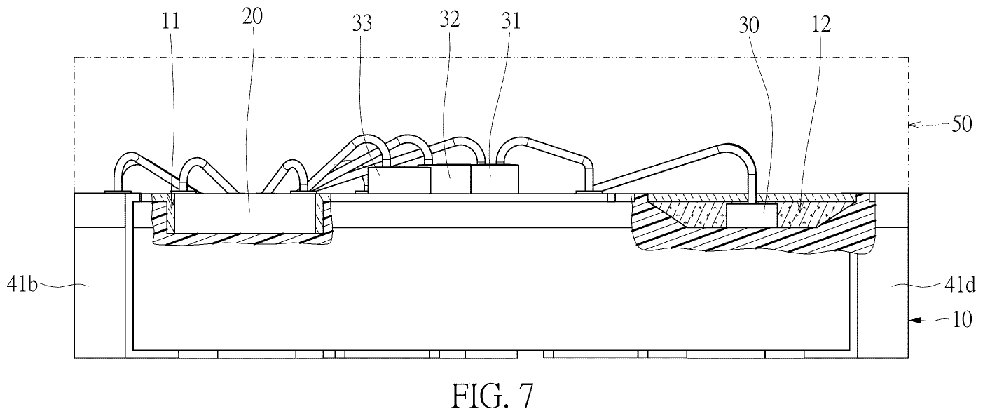

The multi-channel light emitting diode package structure 100 also includes a lens layer 50 that covers at least the upper light emitting chip 31. However, the covering scope of the lens layer 50 is not limited. In this embodiment, the lens layer 50 may be filled with resin, and the lens layer 50 completely covers the top supporting surface 101 of the supporting unit 10. In other words, the lens layer 50 may cover an area that includes the first accommodating portion 11, the second accommodating portion 12, the driver chip 20, at least one upper lighting chip 31, and the lower lighting chip 30, and further is higher than all of metal wires for wiring (which is omitted in FIG. 1, referring to FIG. 7).

The present disclosure arranges the driver chip 20 in the first accommodating portion 11 and the lower light emitting chip 30 in the second accommodating portion 12. The first accommodating portion 11 may be, but is not limited to, a square recess, and the second accommodating portion 12 may be, but is not limited to, a bowl-shaped or basin-shaped recess. At least one of the upper light emitting chips 31 is disposed on the top supporting surface 101 between the first accommodating portion 11 and the second accommodating portion 12. In other words, the top surfaces of the driver chip 20 and the lower lighting chip 30 are both lower than or equal to a bottom surface of the at least one upper lighting chip 31. Through the above structural arrangement, it has at least advantage that the driver chip 20 will not block the light of the upper light emitting chip 31, the light of the lower light emitting chip 30 will not mix with the light of the upper light emitting chip 31, and the upper light emitting chip 31 will not accidentally stimulate the phosphor surrounding the lower light emitting chip 30 to emit unintended light. Thus, the illumination angle can be wider and the light color can be more pure.

In this embodiment, the supporting unit 10 is used to support the driver chip 20 and a plurality of light emitting chips. The supporting unit 10 may be a circuit board and may be a multi-layer printed circuit board. However, the present disclosure is not limited thereto. The first accommodating portion 11 and the second accommodating portion 12 may be formed in one or more layers of the circuit board by drilling or etching.

The driver chip 20 is disposed in the first accommodating portion 11, and the top surface of the driver chip 20 is lower than the top supporting surface 101 of the supporting unit 10. In this embodiment, the driver chip 20 may be, for example, a four-channel LED driver IC for controlling the brightness and the switching state of the light emitting chip.

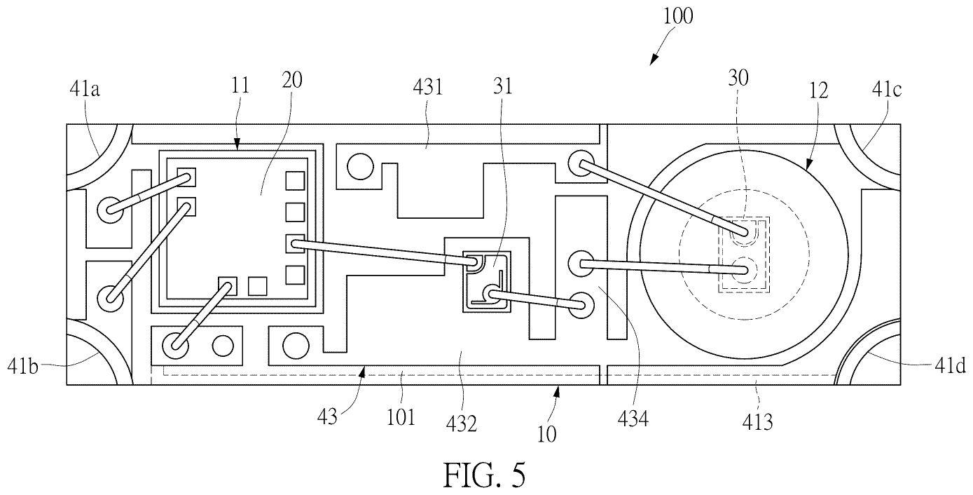

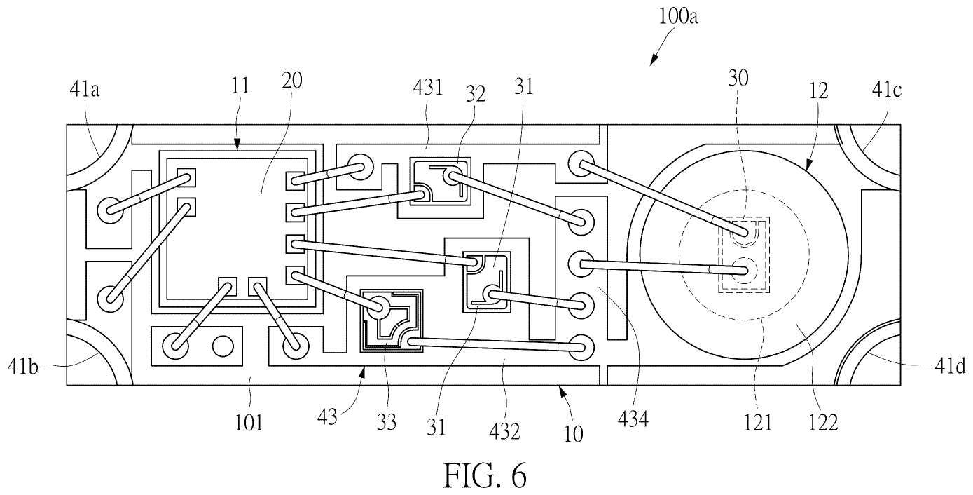

The light emitting chip is a light emitting diode (LED) chip that emits visible light. The number of upper light emitting chips 31 is at least one, which is located on the top supporting surface 101 of the supporting unit 10. The upper light emitting chip 31 is electrically connected to the driver chip 20 through a wire. Referring to FIG. 5, this embodiment of the present disclosure which is equipped with one upper light emitting chip 31 can emit a light of one color. In addition, referring to FIG. 6, another embodiment of the present disclosure with three upper light emitting chips 31, 32, 33 can emit different colors of light. It will be explained in detail later.

Referring to FIG. 1, the lower light emitting chip 30 is disposed in the second accommodating portion 12. The second accommodating portion 12 is filled with phosphor materials 30P, and the phosphor materials 30P completely cover the lower light emitting chip 30. The second accommodating portion 12 of the present embodiment is utilized to provide white light. For example, the lower emitting chip 30 may be a blue LED chip with a wavelength of 445 nm to 475 nm, and the phosphor materials 30P may be yellow phosphor materials or green phosphor materials. A white light can be obtained when the blue light from the light emitting diode is partially converted and mixed by the yellow phosphor or green phosphor.

In another embodiment, referring to FIG. 1, the lower light emitting chip 30 is disposed in the second accommodating portion 12. The second accommodating portion 12 is filled with phosphor materials 30P. The phosphor materials 30P completely cover the lower light emitting chip 30. The second accommodating portion 12 of the present embodiment functions to provide an amber light. The lower emitting chip 30 may be a blue LED chip, for example, the lower emitting chip 30 may be a blue LED chip with a wavelength of 445 nm to 525 nm. The phosphor materials 30P may be red phosphor materials. The blue light from the light emitting diode is partially converted and mixed by the red phosphor to obtain an amber light.

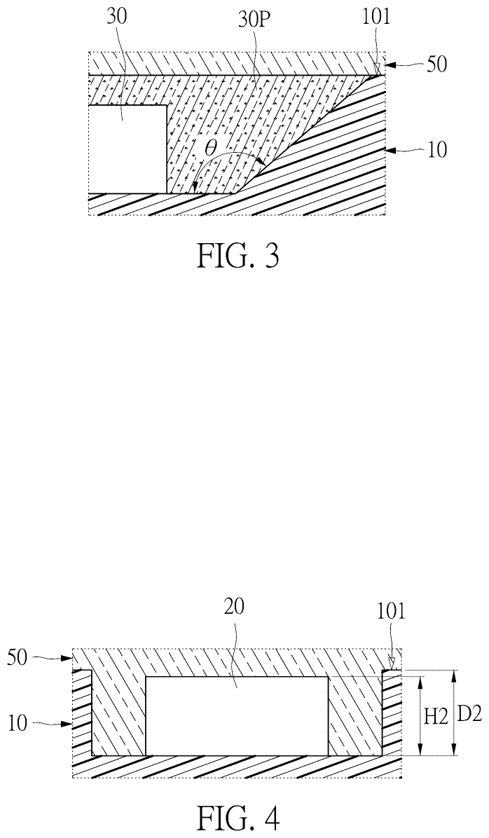

Referring to FIGS. 2 and 3, FIG. 2 is an enlarged view of a part II of FIG. 1, and FIG. 3 is an enlarged view of a part III of FIG. 2. The second accommodating portion 12 includes a bottom surface 121 and a tilted wall surface 122 surrounded by the second accommodating portion 12, which is substantially in the shape of a bowl or basin. An angle θ between the tilted wall surface 122 and the bottom surface 121 is greater than 90 degrees. In this embodiment, the angle θ between the tilted wall surface 122 and the bottom surface 121 is less than or equal to 135 degrees. In addition, the tilted wall surface 122 may be provided with a reflective layer to reflect light.

In this embodiment, the top surface of the lower light emitting chip 30 is lower than the top supporting surface 101 of the supporting unit 10. The top surface of the lower light emitting chip 30 is lower than the top supporting surface 101 of the supporting unit 10 by at least 0.15 mm (centimeter). In other words, a depth D3 of the second accommodating portion 12 is greater than a height H3 of the lower light emitting chip 30 by at least 0.15 mm.

Referring to FIG. 4, FIG. 4 is an enlarged view of a part IV of FIG. 1. In this embodiment, the walls surrounding the driver chip 20 may be perpendicular to the top supporting surface 101 or slightly inclined to the top supporting surface 101 in a generally shallow cup shape. The top surface of the driver chip 20 is at least 0.1 mm below the top supporting surface 101 of the supporting unit 10. In other words, a depth D2 of the first accommodating portion 11 is at least 0.1 mm greater than the height H2 of the driver chip 20.

Referring to FIG. 5, a top schematic view of the multiple-channel light emitting diode package structure of the present disclosure is shown. In this embodiment, the supporting unit 10 is a circuit board, and FIG. 5 shows the circuit layout on the top surface of the circuit board. The circuit board has four corners 41a, 41b, 41c, 41d. Each corner is formed with a partial via. Specifically, each partial via may be formed from a large circuit board forming a plurality of supporting units 10, which are cut to form a quarter of a conductive via to be used as a conductive terminal.

The four corners 41a, 41b, 41c, 41d form a driver chip output portion, and a driver chip input portion, an anode connection portion, and a cathode connection portion, respectively. The driver chip 20 is adjacent to the driver chip output portion (refer to corner 41a) and the driver chip input portion (refer to corner 41b). The second accommodating portion 12 is adjacent to the anode connection portion (refer to corner 41c) and the cathode connection portion (refer to corner 41d). In addition, with a printed circuit board having a multi-layer structure, the cathode connection portion (reference corner 41d) can be electrically connected to the driver chip 20 by an inner wiring layer 413, so as to save the area of the top supporting surface 101. In other words, the supporting unit 10 can be miniaturized.

Referring to FIG. 6, the multi-channel light emitting diode package structure 100a of the present embodiment has three upper light emitting chips 31, 32, 33, which may be, for example, a blue light emitting chip, a red light emitting chip, and a green light emitting chip, respectively.

The following illustrates an embodiment of a circuit configuration for the multi-channel LED package structure of the present disclosure. For example, pins of the driver chip 20 may include an input power terminal (Vin), a signal input terminal (Din), a ground terminal (GND), a signal output terminal (Dout), and four terminals connecting to the cathodes of the LEDs (ILED1 to ILED 4). A conductive layer 43 is formed on the top supporting surface 101 of the supporting unit 10. The conductive layer 43 includes an anode busbar 434, which is electrically connected to an electrode of the upper light emitting chip 31, an electrode of the upper light emitting chip 32, an electrode of the upper light emitting chip 33, and an electrode of the lower light emitting chip 30. Furthermore, the anode busbar 434 is electrically connected to an anode connection portion (41c).

The conductive layer 43 also includes a first chip-mounted area 431, and a second chip-mounted area 432. The first chip-mounted area 431 is disposed between the first accommodating portion 11 and the second accommodating portion 12. The second chip-mounted area 432 is disposed between the first accommodating portion 11 and the anode busbar 434. The anode busbar 434 is disposed between the second chip-mounted area 432 and the second accommodating portion 12. The upper light emitting chip 31 and the upper light emitting chip 33 are disposed in the second chip-mounted area 432. The upper light emitting chip 32 is disposed in the first chip-mounted area 431.

In an embodiment, the upper light emitting chip 31 is a blue light emitting chip, the upper light emitting chip 32 is a green light emitting chip, and the upper light emitting chip 33 is a red light emitting chip.

In another embodiment, the upper light emitting chip 31 is a green light emitting chip, the upper light emitting chip 32 is a blue light emitting chip, and the upper light emitting chip 33 is a red light emitting chip.

### [Beneficial Effect of Implementation]

The beneficial effect of the present disclosure of the multi-channel LED packaging structure is at least that, by virtue of concavely forming a first accommodating portion and a second accommodating portion on the supporting unit, disposing the driver chip in the first accommodating portion, disposing the at least one upper light emitting chip on the top supporting surface of the supporting unit, and disposing the lower light emitting chip in the second accommodating portion, so that the light from the at least one upper light emitting chip and the lower light emitting chip are not obstructed, to increase the light intensity and the viewing angle. Therefore, the lighting effect of the multi-channel light emitting diode package structure is enhanced.

In this embodiment, the top surface of the driver chip and the lower lighting chip are both lower than or equal to the bottom surface of the upper lighting chip. The top surface of the phosphor materials is also lower than or equal to the bottom surface of the upper emitter. The blue light from the upper emitting chip does not excite the phosphor materials in the second accommodating portion so as to avoid from producing unintended light.

In addition, the multi-channel light emitting diode package structure of the present disclosure also provides an embodiment of circuit configuration that can save an area of the top supporting surface. In other words, the supporting unit can be miniaturized.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A multi-channel light emitting diode package structure, comprising:
a supporting unit having a top supporting surface, the supporting unit including a first accommodating portion and a second accommodating portion that both are concaved from the top supporting surface;
a driver chip disposed in the first accommodating portion, a top surface of the driver chip being lower than a top surface of the supporting unit;
at least one upper light emitting chip disposed on the top supporting surface of the supporting unit; and
a lower light emitting chip disposed in the second accommodating portion, the lower light emitting chip having a top surface lower than the top supporting surface of the supporting unit, wherein the second accommodating portion is filled with phosphor materials, and the phosphor materials completely cover the lower light emitting chip.

2. The multi-channel light emitting diode package structure according to claim 1, further comprising a lens layer, the lens layer covering at least the at least one upper light emitting chip.

3. The multi-channel light emitting diode package structure according to claim 1, wherein the at least one upper light emitting chip is disposed between the first accommodating portion and the second accommodating portion.

4. The multi-channel light emitting diode package structure according to claim 1, wherein the top surface of the driver chip is at least 0.1 centimeters below the top supporting surface of the supporting unit.

5. The multi-channel light emitting diode package structure according to claim 1, wherein the top surface of the lower light emitting chip is at least 0.15 centimeters below the top supporting surface of the supporting unit.

6. The multi-channel light emitting diode packaging structure according to claim 1, wherein the second accommodating portion is formed with a bottom surface and surrounded by a tilted wall surface, and wherein an included angle between the tilted wall surface and the bottom surface is greater than 90 degrees.

7. The multi-channel light emitting diode package structure according to claim 6, wherein the included angle between the tilted wall surface and the bottom surface is less than or equal to 135 degrees.

8. The multi-channel light emitting diode package structure according to claim 6, wherein a reflective layer is formed on the tilted wall surface.

9. The multi-channel light emitting diode package structure according to claim 1, wherein the supporting unit is a circuit board with four corners, each of the corners forms a partial through-hole, and the four corners respectively serve as an anode connection portion, a cathode connection portion, a driver chip output portion, and a driver chip input portion.

10. The multi-channel light emitting diode package structure according to claim 9, wherein the circuit board is multi-layered, and the cathode connection portion is electrically connected to the driver chip through an inner wiring layer.

11. The multi-channel light emitting diode package structure according to claim 9, wherein the driver chip is adjacent to the driver chip output portion and the driver chip input portion, wherein the second accommodating portion is adjacent to the anode connection portion and the cathode connection portion.

12. The multi-channel light emitting diode package structure according to claim 11, wherein the at least one upper light emitting chip includes a blue light emitting chip, a red light emitting chip, and a green light emitting chip, wherein the lower light emitting chip emits blue light, and the phosphor materials receive the blue light to emit white light.

13. The multi-channel light emitting diode package structure according to claim 12, wherein the top supporting surface of the supporting unit forms a conductive layer, the conductive layer includes an anode busbar, wherein the anode busbar is electrically connected to an electrode of the blue light emitting chip, an electrode of the red light emitting chip, an electrode of the green light emitting chip, an electrode of the lower light emitting chip and the anode connection portion.

14. The multi-channel light emitting diode package structure according to claim 13, wherein the conductive layer further includes a first chip-mounted area and a second chip-mounted area, the first chip-mounted area is disposed between the first accommodating portion and the second accommodating portion, the second chip-mounted area is disposed between the first accommodating portion and the anode busbar, and the anode busbar is disposed between the second chip-mounted area and the second accommodating portion.

15. The multi-channel light emitting diode package structure according to claim 14, wherein the blue light emitting chip and the red light emitting chip are disposed in the second chip-mounted area, wherein the green light emitting chip is disposed in the first chip-mounted area.

16. The multi-channel light emitting diode package structure according to claim 14, wherein the green light emitting chip and the red light emitting chip are disposed in the second chip-mounted area, wherein the blue light emitting chip is disposed in the first chip-mounted area.

17. The multi-channel light emitting diode package structure according to claim 11, wherein the at least one upper light emitting chip includes a blue light emitting chip, a red light emitting chip, and a green light emitting chip, wherein the lower light emitting chip emits blue light, and the phosphor materials receive the blue light to emit amber light.

18. The multi-channel light emitting diode package structure according to claim 17, wherein the top supporting surface of the supporting unit has a conductive layer, the conductive layer includes an anode busbar, wherein the anode busbar is electrically connected to an electrode of the blue light emitting chip, an electrode of the red light emitting chip, an electrode of the green light emitting chip, an electrode of the lower light emitting chip, and the anode connection portion.

19. The multi-channel light emitting diode package structure according to claim 18, wherein the conductive layer further includes a first chip-mounted area, and a second chip-mounted area, the first chip-mounted area is disposed between the first accommodating portion and the second accommodating portion, the second chip-mounted area is disposed between the first accommodating portion and the anode busbar, and the anode busbar is disposed between the second chip-mounted area and the second accommodating portion.

20. The multi-channel light emitting diode package structure according to claim 19, wherein the blue light emitting chip and the red light emitting chip are disposed in the second chip-mounted area, wherein the green light emitting chip is disposed in the first chip-mounted area.

21. The multi-channel light emitting diode package structure according to claim 19, wherein the green light emitting chip and the red light emitting chip are disposed in the second chip-mounted area, wherein the blue light emitting chip is disposed in the first chip-mounted area.
